(19) United States
(12) Patent Application Publication
(10) Pub. No.: US 2026/0334303 A1
(43) Pub. Date: Oct. 22, 2026

(54) HETEROGENEOUS INTEGRATED ELECTRO-OPTICAL APPARATUS

(71) Applicant: Taiwan Semiconductor Manufacturing Co., Ltd., Hsinchu (TW)

(72) Inventor: Chan-Hong Chern, Palo Alto, CA (US)

(21) Appl. No.: 19/182,204

(22) Filed: Apr. 17, 2025

(51) Int. Cl. H01L 25/16; G02B 6/42; G02B 6/43; H01L 23/00; H01L 23/498; H01L 25/00

(52) U.S. Cl. CPC H10W 90/00; G02B 6/428; G02B 6/43; H10W 70/635; H10W 70/65; H10W 90/701; H10W 90/724

(57) ABSTRACT

In some embodiments, a device is provided that includes a logic die bonded to a first portion of a substrate, wherein the logic die includes a first signal serialization device and the substrate includes at least one redistribution layer. The device further includes an Electrical Integrated Circuit (EIC) die bonded to a second portion of the substrate, the EIC die comprises III-V type devices, silicon germanium type devices, or a combination thereof, the EIC die includes a second signal serialization device, wherein a second portion of the at least one redistribution layer of the substrate provides for a first signal transmission path between the logic die and the EIC die. The device may further include a Photonics Integrated Circuit (PIC) die including an edge coupler, wherein a second signal transmission path extends between the between the PIC die and the EIC die.

### BACKGROUND

Electrical signaling and processing is one technique for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating long-range optical components and short-range electrical components are formed for the conversion between optical signals and electrical signals, as well as the processing of optical signals and electrical signals. Packages thus may include both optical (photonic) dies including optical devices and electronic dies including electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram illustrating logic die coupled to an optical module including an Electrical Integrated Circuit (EIC) die and Photonics Integrated Circuit (PIC) die, in which the EIC die includes semiconductor devices based on silicon germanium (SiGe) and/or type III-V semiconductor material, in accordance with some embodiments;

FIG. 2 is a block diagram illustrating transmission of optical signals between two electro-optical apparatus, in which the path of electrical signal serialization for conversion to optical signal is illustrated between the logic die, the EIC die and the PIC die, in accordance with some embodiments;

FIG. 3 is a side cross-sectional view illustrating an interposer used in a method for forming a PIC die, in accordance with some embodiments;

FIG. 4 is a side cross-sectional view illustrating processing the interposer to provide optical components, in accordance with some embodiments;

FIG. 5 is a side cross-sectional view illustrating forming a front-side edge coupler, in accordance with some embodiments;

FIG. 6 is a side cross-sectional view illustrating a waveguide connected to an optical cable through an edge coupler, in accordance with some embodiments;

FIG. 7 is a side cross-sectional view illustrating a PIC die being flipped, and performing back-side processing to prepare the structure for forming a back-side edge coupler, in accordance with some embodiments;

FIG. 8 is a side cross-sectional view illustrating forming a back-side edge coupler on the back-side surface of the optical components, in accordance with some embodiments;

FIG. 9 is a side cross-sectional view illustrating a PIC die having a back-side edge coupler, in accordance with some embodiments;

FIG. 10 is a side cross-sectional view illustrating forming a redistribution layer substrate, in accordance with some embodiments;

FIG. 11 is a side cross-sectional view illustrating bonding a logic die, EIC die and PIC die to the redistribution layer substrate, in accordance with some embodiments;

FIG. 12 is a side cross-sectional view illustrating bonding an assembly of the logic die, the EIC die and the PIC die and the redistribution layer substrate to a packaging substrate, in accordance with some embodiments;

FIG. 13 is a side cross-sectional view illustrating an electro-optical assembly including a logic die, EIC die and PIC die bonded to an interposer substrate, in which the interposer substrate is bonded to a redistribution layer substrate that is bonded to a packaging substrate, in accordance with some embodiments;

FIG. 14 is a side cross-sectional view of an electro-optical assembly including a PIC die vertically stacked on a EIC die, in accordance with some embodiments; and

FIG. 15 is a side cross sectional view illustrating an electro-optical assembly including a redistribution layer (RDL) substrate connected to a packaging substrate through wire bonds, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In three dimensionally packaged devices, electrical transmission of data at high frequency or high data rate may not be able to travel long distance due to high energy loss in electrical transmission mediums. In three dimensionally packaged devices, logic devices, such as those employed for switching (e.g., CMOS switch) or SOC (System On Chip, e.g. ASIC, CPU, GPU, etc.) are generally coupled to an optical module, and reply on the optical module to transmit/receive long-distance signals through an optical transmission medium, such as optical fibers. In some embodiments, the optical module is composed of a Photonics Integrated Circuit (PIC) die and an Electrical Integrated Circuit (EIC) die. In typical optical modules, CMOS transistors based on silicon (Si) may provide for the transmission of electrical signals between the EIC die and the PIC die, or CMOS transistors based on silicon (Si) may provide for transmission of electric signals between the EIC die and the logic die. However, the bandwidth of CMOS transistors based on silicon is not scaled for advanced technology nodes. As such, in some examples, CMOS electrical transceiver circuits based on silicon (Si) is a limiting factor for achieving data rates greater than 200 Gbps. Further, for achieving significantly higher operating frequency or data rate, optical components of the PIC die, such as the modulator, can demand a high operating voltage, e.g., 3.5V or greater. In some embodiments, CMOS electrical transistors based on silicon (Si) can not operate at the high operating voltage that the modulator of the PIC die operates at for high data rate applications.

In some embodiments, the above described disadvantages in electrical signal transmission and operating limitations at high voltages that are typical of silicon (Si) based CMOS transistors are overcome by configuring the EIC die of an optical module with semiconductor devices based on type III-V semiconductor materials and/or semiconductor devices based on silicon germanium (SiGe). For example, an optical module including an EIC die with transistors based on III-V semiconductor materials and/or silicon germanium (SiGe) can have electrical signal transmission rates as great as 400 GB/s or greater, whereas CMOS transistors based on silicon (Si) are limited to transmission rates of 200 GB/s or less.

The embodiments presented herein are intended to be illustrative and are not intended to limit the ideas presented to the precise embodiments described. Rather, the ideas presented may be incorporated into a wide variety of embodiments, and all such embodiments may be included within the overall scope of the disclosure.

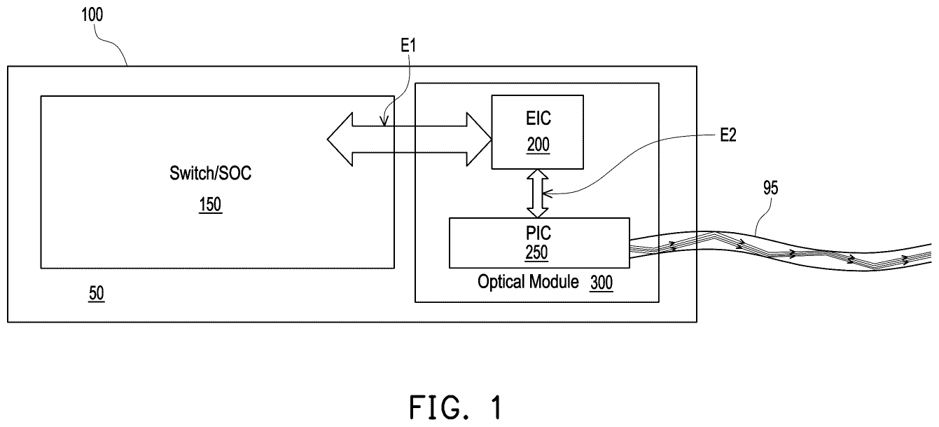

With reference now to FIG. 1, there is illustrated a block diagram illustrating the connectivity of an EIC die including high operating voltage and high-speed SiGe/III-V transistors between the logic die and the PIC die. The electrical signals between the logic die and the EIC die can remain at relatively low transmission speed, e.g. 50 GHz or 200 Gbps. However, the transmission of electrical signals in between the EIC die and the PIC die are boosted to significantly higher speed, e.g. 100 GHz or 400 Gbps.

FIG. 1 shows a block diagram which heterogeneously integrates high operating voltage and high-speed semiconductor devices, such as semiconductor devices based on silicon germanium (SiGe) and/or type III-V semiconductor materials, and CMOS semiconductor devices based on silicon (Si) that are included in logic die 150. In the embodiments depicted in FIG. 1, a packaged optical device is illustrated including an EIC die 200 positioned between a logic die 150 and a PIC die 250. The logic die 150 may be a Switch or SOC (System On Chip). Examples of components within a SOC can include an application specific integrated circuit (ASIC), a central processing unit (CPU), a graphics processing unit (GPU) and combinations thereof. In other embodiments, the logic die 150 may be or may comprise processor dies, memory dies, input-output dies, Integrated Passive Devices (IPDs), the like, or combinations thereof. For example, the processor dies in chip-on-interposer components may be Central Processing Unit (CPU) dies, Graphic Processing Unit (GPU) dies, mobile application dies, Micro Control Unit (MCU) dies, BaseBand (BB) dies, Application Processor (AP) dies, or the like. The memory dies in logic die 150 may include Static Random-Access Memory (SRAM) dies, Dynamic Random-Access Memory (DRAM) dies, or the like.

In some embodiments, the EIC die 200 can use electrical signals to transmit and/or process data. The EIC die 200 is a chip that uses electronic components like semiconductor devices to process data. The semiconductor devices employed by the EIC die 200 described herein can be either type III-V semiconductor devices and/or germanium containing semiconductor devices, e.g., silicon germanium (SiGe) channel semiconductor devices. Embodiments have been contemplated in which the semiconductor devices of the EIC die 200 are type III-V semiconductor devices. Embodiments have been contemplated in which the semiconductor devices of the EIC die 200 are silicon germanium channel semiconductor devices. By being a silicon germanium channel semiconductor device at least the channel region of the semiconductor device is composed of silicon germanium. In some embodiments, the EIC die 200 includes both type III-V semiconductor devices and/or silicon germanium channel devices. Each transistor includes source/drain regions doped to a p-type or n-type conductivity between a channel region. Conductivity across the channel region is controlled by a gate structure that is on the channel region. By being based on a type III-V material or silicon germanium (SiGe), at the channel region of a semiconductor device is composed of the type III-V semiconductor material or silicon germanium (SiGe). In some embodiments, for a type III-V material or silicon germanium based semiconductor device both the source/drain regions and the channel region may be composed of type III-V semiconductor material or silicon germanium (SiGe). In some embodiments, the semiconductor devices in the EIC die 200 may include field effect transistors, p-type transistors, n-type transistors, bipolar junction transistors, fin field effect transistors (FinFETs), planar transistors, nano-FETs, combinations thereof, or the like. It is noted that the aforementioned description of semiconductor device types for the EIC die 200 are provided for illustrative purposes only, and are not intended to limit the present disclosure.

A type III-V semiconductor material is composed of elements from group III and group V of the periodic table of elements. In one embodiment, at least one transistor in the EIC die 200 is comprised of at least one type III-V semiconductor material selected from the group consisting of aluminum antimonide (AlSb), aluminum arsenide (AlAs), aluminum nitride (AlN), aluminum phosphide (AlP), gallium arsenide (GaAs), gallium phosphide (GaP), indium antimonide (InSb), indium arsenic (InAs), indium nitride (InN), indium phosphide (InP), aluminum gallium arsenide (AlGaAs), indium gallium phosphide (InGaP), aluminum indium arsenic (AlInAs), aluminum indium antimonide (AlInSb), gallium arsenide nitride (GaAsN), gallium arsenide antimonide (GaAsSb), aluminum gallium nitride (AlGaN), aluminum gallium phosphide (AlGaP), indium gallium nitride (InGaN), indium arsenide antimonide (InAsSb), indium gallium antimonide (InGaSb), aluminum gallium indium phosphide (AlGaInP), aluminum gallium arsenide phosphide (AlGaAsP), indium gallium arsenide phosphide (InGaAsP), indium arsenide antimonide phosphide (InArSbP), aluminum indium arsenide phosphide (AlInAsP), aluminum gallium arsenide nitride (AlGaAsN), indium gallium arsenide nitride (InGaAsN), indium aluminum arsenide nitride (InAlAsN), gallium arsenide antimonide nitride (GaAsSbN), gallium indium nitride arsenide aluminum antimonide (GaInNAsSb), gallium indium arsenide antimonide phosphide (GaInAsSbP), and combinations thereof.

In comparison to complementary metal oxide semiconductor (CMOS) device based upon a silicon (Si) channel, a similar arrangement of type III-V semiconductor-based material can provide increased carrier mobility, e.g., increased electron mobility. The III-V semiconductor-based transistors when employed as the transistors of the EIC die 200 may result in high electrical transmission rates being greater than 200 GB/s. For example, electrical transmission rates can be increased to 400 GB/s or greater by implementing III-V semiconductor-based transistors into the EIC die 200. In comparison, an EIC die 200 employing silicon (Si) based transistors, such as pure silicon (Si) CMOS, have an electrical transmission rate limited to 200 GB/s or less.

Silicon germanium (SiGe) based transistors also have an increased carrier mobility when compared to silicon (Si) based transistors. The increased carrier mobility results from the band gap of silicon germanium (SiGe). More particularly, SiGe utilizes a heterojunction structure, where the addition of germanium to silicon creates a different bandgap, allowing for improved carrier transport. Similar to III-V semiconductor-based transistors, when silicon germanium-based transistors are employed as the transistors of the EIC die 200 an increased electrical transmission rate may be achieved when compared to the electrical transmission rate of silicon based transistors. For example, electrical transmission rates can be increased to 400 GB/s or greater by implementing SiGe semiconductor-based transistors into the EIC die 200.

The PIC die 250 receives, modulates, and transmits optical (e.g., light) signals. For example, the PIC die 250 uses optical components like waveguides and lasers to manipulate light for data transmission, essentially operating on photons instead of electrons. In addition to waveguides and lasers, the PIC die 250 further includes modulators and detectors. For example, the PIC die 250 may include O-E/E-O converters, a modulation driver, and transimpedance amplifier (TIA). Electro-optic (EO) modulation in photonics is a process that changes the optical properties of a material using an electric field. A modulation driver/TIA is a combination of a modulator driver and a transimpedance amplifier (TIA) that are used in optical networking applications. The semiconductor devices based on type III-V semiconductor materials and/or silicon germanium in the EIC die 200, provides that the PIC die 1250 can operate at voltages capable of driving a high-speed modulator. In some embodiments, the ability for the operating voltages to drive the modulator can enlarge the Optical Modulation Amplitude (OMA) by providing a large swing for Trans-Impedance-Amplifier (TIA) in the high-speed EIC 200. In some examples, the transimpedance amplifier (TIA) can amplify a current signal from a photodetector. The PIC die 250 may be connected to an optical fiber 95 for transmission of optical signals to/from the PIC die 250. The PIC die 250 and the EIC die 200 may be integrated into an optical module 300.

FIG. 1 illustrates that the logic die 150, the EIC die 200 and the PIC die 250 being packaged in a 2.5D or 3D package, in which the logic die 150, the EIC die 200 and the PIC die 250 is bonded to a supporting structure that may include an interposer/substrate 50. In some embodiments, the first electrical signals E1 between the logic die 150 and the EIC die 200 may be at a relatively lower speed, e.g., 50 GHz or 200 Gbps, than the electrical signals E2 between the EIC die 200 and the PIC die 250. In some embodiments, the second electrical signals E2 between the EIC die 20o and the PIC die 250 can be boosted to a significantly higher speed, e.g. 100 GHz or 400 Gbps, than the transmission speed for the electrical signal E1 between the logic die 150 and the EIC die 200. The physical bonding that provides the pathway for the first electrical signals E1 transmitted between the logic die 15o and the EIC die 200 can include bonded type electrical joints, such as C4 solder bumps, microbumps, direct bonding, e.g., copper to copper bonding, and/or hybrid bonding. The physical bonding that provides the pathway for the second electrical signals E2 transmitted between the EIC die 200 and the PIC die 250 can similarly be provided by bonded type electrical joints, such as micro bumps, direct bonding, e.g., copper to copper bonding, and/or hybrid bonding.

The optical signals from the PIC die 250 can be transmitted through the optical fiber 95, and can be boosted up to high speeds, e.g., 100 GHz or 400 Gbps, due to high-operating voltage capability/high-speed modulation capability of the semiconductor devices based upon type III-V semiconductors and/or silicon germanium within the EIC die 200. Further, the optical signal from the PIC die 250 can then be transmitted along long distance by optical fiber 95, e.g. ranging from 10 meter to 2 kilometers.

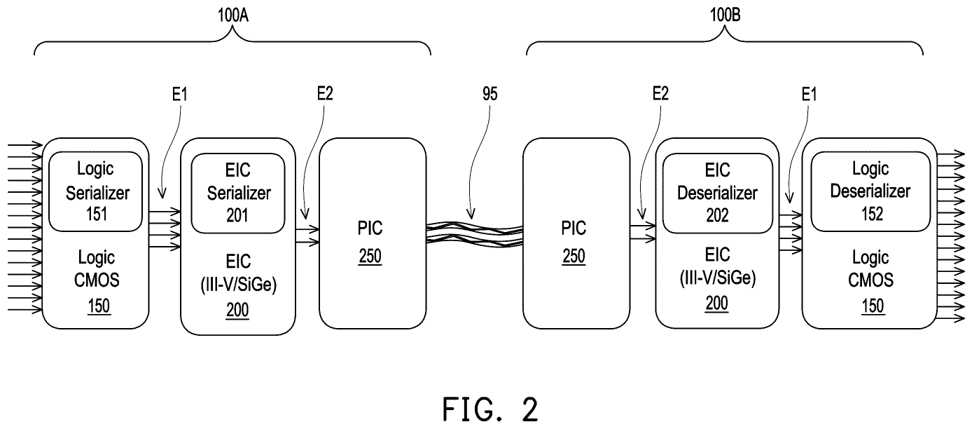

FIG. 2 is a block diagram illustrating transmission of optical signal across an optical fiber 95 between a first electro-optical apparatus 100A and a second electro-optical apparatus 100B, in which the path of signal serialization between the logic die 150, the EIC die 200 and the PIC die 250 is illustrated. In some embodiments, serialization includes converting parallel data (multiple data streams) into a single serial data stream of bits that can be transmitted through an optical fiber 95, while deserialization is the reverse process. In FIG. 2, serialization is illustrated in the first electro-optical apparatus 100A, and deserialization is illustrated in the second electro-optical apparatus 100B. Each of the electro-optical apparatus 100A, 100B include co-packaged logic die 150, e.g., SOC/Switch, and optical module, e.g., PIC die 250 and EIC die 200.

In some embodiments, the serialization/deserialization from the logic die 150 to the PIC die 250 is provided in two parts. For example, for transmission of the electrical signal E1 from the logic die 150 to the EIC die 200 in the first electro-optical apparatus 100A, a first stage of serialization is performed. The first stage of serialization for the electrical signal E1 from the logic die 150 may be provided by a first serializer 151 in the logic die 150. For transmission of the electrical signal E2 from the EIC die 200 to the PIC die 250 within the first electro-optical apparatus 100A, a second stage of serialization is performed. The second stage of serialization for the electrical signal E2 from the EIC die 200 may be provided by a second serializer 201 in the EIC die 200. The first serializer 151 in the logic die 150 of the first electro-optical apparatus 100A, the second serializer 201 in the EIC die 200 of the first electro-optical apparatus 100A may each be provided by circuitry providing a serializer/deserializer (SerDes) component.

Following the two stages of serialization in the first electro-optical apparatus 100A, the PIC die 250 receives the signal, and then may transmit the signal optically through an optical fiber 95 to the second electro-optical apparatus 100B. In the example illustrated in FIG. 2, the optical signal from the first electro-optical apparatus 100A is received by the PIC die 250 of the second electro-optical apparatus 100B. In the second electro-optical apparatus 100B, the signal E2 from the PIC die 250 is transmitted to the EIC die 200 at which a first stage of deserialization of the signal is performed. The first stage of deserialization may be performed by a second deserializer 202 in the EIC die 200. After the first stage of deserialization, a second stage of deserialization is performed for the signal E1 being transmitted from the EIC die 200 to the logic die 150. The second stage of deserialization for the electrical signal E1 from the EIC die 200 to the logic die 150 may be provided by a first deserializer 152 in the logic die 150.

Following the two stages of deserialization in the second electro-optical apparatus 100B, the logic die 150 receives the signal for processing. The second deserializer 202 in the EIC die 200 of the second electro-optical apparatus 100B, and the first deserializer 152 in the logic die 150 of the second electro-optical apparatus 100B may each be provided by circuitry providing a serializer/deserializer (SerDes) component. SERDES technology can include a transmitter (TX) block, which serializes the parallel data, and a receiver (RX) block, which deserializes the serial data back into parallel form. In addition, SERDES circuits often include clock and data recovery (CDR) circuits, equalizers, data alignment, and error detection and correction mechanisms to ensure accurate and reliable data transmission over a communication channel.

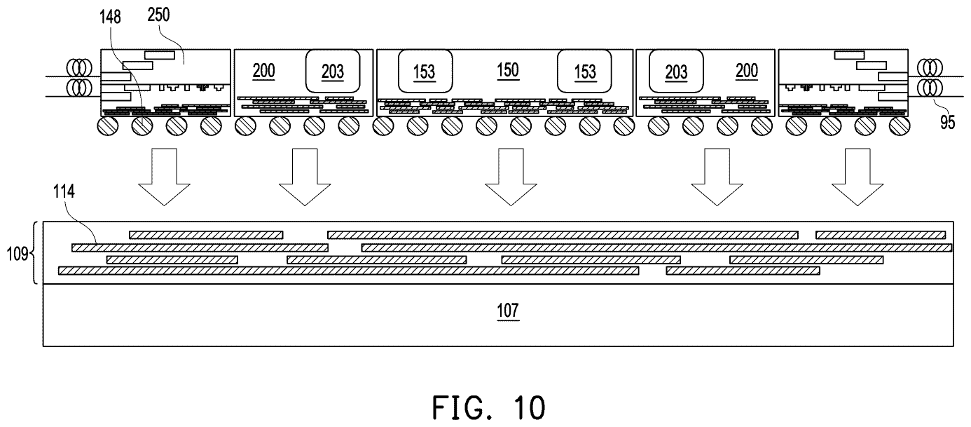

In the following description, the first serializer 151 and the first deserializer 152 of the logic die 150 may be collectively referred to as a first serialization device 153 (depicted in FIGS. 10-15). In the following description, the second serializer 201 and the second deserializer 202 of the EIC die 200 may be collectively referred to as a second serialization device 203 (depicted in FIGS. 10-15).

Each of the first electro-optical apparatus 100A and the second electro-optical apparatus 100B includes transistors that are silicon (Si) based, such as the CMOS transistors in the logic die 150. Further, each of the first electro-optical apparatus 100A and the second electro-optical apparatus 100B includes and EIC die 200 that includes semiconductor devices that are based on type III-V semiconductor and/or silicon germanium (SiGe). The different transistor types, e.g., silicon-based transistors vs. III-V/SiGe based transistors, have different electrical signal transmission rates, yet are heterogeneously integrated into the same electro-optical device.

To take advantage of the different transmission rates, two stages of serialization/deserialization are employed, in which a lesser amount of serialization/deserialization may be performed at the logic die 150 than at the EIC die 200. In some embodiments, the serializer 201/deserializer 202 that is integrated into the EIC die 200 provides for a portion of the serialization/deserialization to be performed in the EIC die 200 including the higher transmission rate III-V or SiGe transistors that is separate from the serialization/deserialization that is performed at the logic die 150. Because a serializer 201/deserializer 202 is integrated into the EIC die 200, a lesser amount of serialization/deserialization is performed at the serializer 151/deserializer 152 of the logic die 150. Serialization/deserialization is performed by the serializer 201/deserializer 202 in the high-speed EIC die 200 to provide for optimum final serialization/deserialization. By providing the separate serializer 151/deserializer 152 in the logic die 150, the degree of serialization for the signal E1 between the logic die and the EIC die 200 may be adjusted to be suitable for the lower transmission rates of the silicon-based CMOS transistors in the logic die 150.

This allows for optimum signal transmission as the data rate for the silicon-based CMOS transistors in the logic die 150 is less than the data rate for the III-V and/or SiGe based transistors the EIC die 200. For example, the highest achievable data rates for the silicon-based CMOS circuits of the logic die 150 that transmits the first electrical signal E1 between the logic die 150 and the EIC die 200 is about 50 GHz or 200 Gbps, whereas the highest achievable rates for the type III-V based transistors and/or SiGe based transistors of the EIC die 200 that transmits the electrical signal E1 to the PIC die 250 may be 100 GHz or 400 Gbps. In some embodiments, the degree of serialization/deserialization by the serializer 151/deserializer 152 within the logic die 150 is less than the degree of serialization/deserialization by the serializer/deserializer 201/202 within the EIC die 200. By employing a greater degree of serialization/deserialization in the EIC die 200, the transceiver speed and modulator driving voltage between the EIC die 200 and PIC die 250 can be boosted up (e.g. 100GHz or 400 Gbps and >3.5V) by the SiGe/III-V based transistors of the EIC die 200, without significantly impacting the performance at the logic die 150.

The photonics integrated circuit (PIC) die 250 may include at least one of a front-side edge coupler, a back-side edge coupler or a combination of a front-side edge coupler and a back-side edge coupler. Each of the front-side edge coupler and the back-side edge coupler are connected to an optical fiber 95.

FIGS. 3-5 illustrate one embodiment of forming a front-side edge coupler 45 in a photonics integrated circuit (PIC) die 250. FIG. 3 illustrates an initial structure of an optical interposer 10. In the particular embodiment illustrated in FIG. 3, the optical interposer 10 is for producing a photonic integrated circuit (PIC) die and comprises at this stage a first substrate 11, a first insulator layer 13, and a layer of material for a first active layer 20 of first optical components 21. In an embodiment, at a beginning of the manufacturing process of the optical interposer 10, the first substrate 11, the first insulator layer 13, and the layer of material for the first active layer 20 of the first optical components 21 may collectively be part of a silicon-on-insulator (SOI) substrate. Looking first at the first substrate 11, the first substrate 11 may be a semiconductor material such as silicon or germanium, a dielectric material such as glass, or any other suitable material that allows for structural support of overlying devices.

The first insulator layer 13 may be a dielectric layer that separates the first substrate 11 from the overlying first active layer 20 and can additionally, in some embodiments, serve as a portion of cladding material that surrounds the subsequently manufactured first optical components 21. In an embodiment the first insulator layer 13 may be silicon oxide, silicon nitride, germanium oxide, germanium nitride, combinations of these, or the like, formed using a method such as implantation (e.g., to form a buried oxide (BOX) layer) or else may be deposited onto the optical interposer 10 using a deposition method such as chemical vapor deposition, atomic layer deposition, physical vapor deposition, combinations of these, or the like. However, any suitable material and method of manufacture may be used.

The material for the first active layer 20 is initially (prior to patterning) a conformal layer of material that will be used to manufacture the first optical components 21. In an embodiment the material for the first active layer 20 may be a translucent material that can be used as a core material for the desired first optical components 21, such as a semiconductor material such as silicon, germanium, silicon germanium, combinations of these, or the like, while in other embodiments the material for the first active layer 20 may be a dielectric material such as silicon nitride or the like, although in other embodiments the material for the first active layer 20 may be III-V materials, lithium niobate materials, or polymers. In embodiments in which the material of the first active layer 20 is deposited, the material for the first active layer 20 may be deposited using a method such as epitaxial growth, chemical vapor deposition, atomic layer deposition, physical vapor deposition, combinations of these, or the like. In other embodiments in which the first insulator layer 13 is formed using an implantation method, the material of the first active layer 20 may initially be part of the first substrate 101 prior to the implantation process to form the first insulation layer 13. However, any suitable materials and methods of manufacture may be utilized to form the material of the first active layer 20.

FIG. 4 illustrates that once the material for the first active layer 20 is ready, the first optical components 21 for the first active layer 20 are manufactured using the material for the first active layer 20. In embodiments the first optical components 21 of the first active layer 20 may include such components as optical waveguides (e.g., ridge waveguides, rib waveguides, buried channel waveguides, diffused waveguides, etc.), couplers, directional couplers, optical modulators (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like.

To begin forming the first active layer 20 of the first optical components 21 from the initial material, the material for the first active layer 20 may be patterned into the desired shapes for the first active layer of first optical components 21. In an embodiment the material for the first active layer 20 may be patterned using, e.g., one or more photolithographic masking and etching processes. However, any suitable method of patterning the material for the first active layer 20 may be utilized. For some of the first optical components 21, the patterning process may be all or at least most of the manufacturing that is used to form these first optical components 21.

FIG. 4 also illustrates that, for those components that utilize further manufacturing processes, such as Mach-Zehnder silicon-photonic switches that utilize resistive heating elements, additional processing may be performed either before or after the patterning of the material for the first active layer 20 for forming the first optical components 21. For example, implantation processes, additional deposition and patterning processes for different materials (e.g., resistive heating elements, III-V materials for converters), combinations of all of these processes, or the like, can be utilized to help further the manufacturing of the various desired first optical components 21. In a particular embodiment, and as specifically illustrated in FIG. 3, in some embodiments an epitaxial deposition of a semiconductor material 31 such as germanium (used, e.g., for electricity/optics signal modulation and transversion) may be performed on a patterned portion of the material of the first active layer 20. In such an embodiment the semiconductor material 31 may be epitaxially grown in order to help manufacture, e.g., a photodiode for an optical-to-electrical converter. All such manufacturing processes and all suitable first optical components 21 may be manufactured, and all such combinations are fully intended to be included within the scope of the embodiments.

FIG. 4 illustrates that, once the first optical components 21 have been formed, a second dielectric layer 40 may be deposited onto the first optical components 21. In some embodiments, the upper surface of the second dielectric layer 40 is planarized to provide that the upper surface of the second dielectric layer 40 is coplanar with the upper surface of the first optical components 21. However, the second dielectric layer 40 may cover the first optical components 21. In an embodiment, the second dielectric layer 40 may be a dielectric layer that separates the individual components of the first active layer 20 from each other and from the overlying structures. In an embodiment, the second dielectric layer 40 may be silicon oxide, silicon nitride, germanium oxide, germanium nitride, combinations of these, or the like, formed using a deposition method such as chemical vapor deposition, atomic layer deposition, physical vapor deposition, combinations of these, or the like. However, any suitable material and method of manufacture may be used.

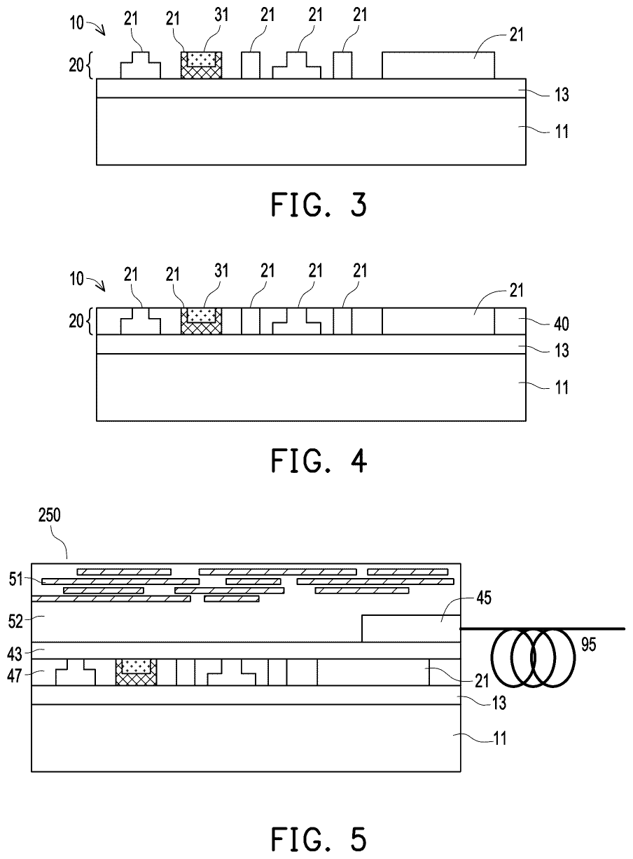

FIG. 5 illustrates that, once the first optical components 21 have been manufactured and the second insulator layer 40 has been formed, the front-side edge coupler 45 may be formed. The front-side edge coupler 45 is for connecting to the optical fiber 95 for the transmission or reception of optical cable to the PIC die 250. For example, the front-side edge coupler 45 may connect the optical fiber 95 to a waveguide component that is in communication with the first optical components 21. In some embodiments, a disclosed front-side edge coupler 45 is located at an edge of a photonic device (PIC die 250) and is configured for optically coupling the waveguide that is in communication with the first optical components 21 to an optical fiber 95.

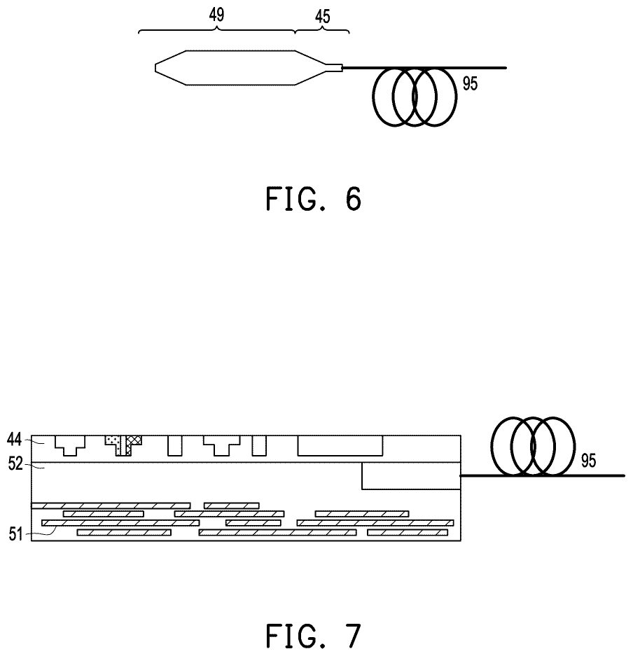

FIG. 6 illustrates one embodiment of a front-side edge coupler 45 interfacing with an optical waveguide 49. Optical applications may use different fiber types with different mode field diameters (MFDs), e.g., varying from 2 to 30 micrometers. It is not straightforward to build a light-coupling interface, e.g., a front-side edge coupler 45, to transmit optical signals between a bulky optical fiber 95 and a smaller optical waveguide 49. In some embodiments, the front-side edge coupler 45 and the optical waveguide 49 may each be composed of silicon nitride. In some embodiments, the front-side edge coupler 45 is a spot size edge coupler. A spot size edge coupler is a type of optical device used to couple light from a fiber optic cable to a waveguide by utilizing a spot size converter (SSC) at the edge of the chip to match the different mode sizes of the fiber and the waveguide, allowing for efficient light transfer between the two mediums. In some embodiments, the spot size converter acts as a bridge to smoothly transition the light from the larger fiber mode to the smaller waveguide mode at the edge of the chip.

In the embodiment depicted in FIG. 5, the front-side edge coupler 45 is formed by depositing a third dielectric layer 43 onto the first optical components 21 and the second dielectric layer 40. The third dielectric layer 43 may provide a layer of cladding for a waveguide element of the first optical components 21. The third dielectric layer 43 may be composed of any of the aforementioned dielectric materials that are used for the second dielectric layer 40. In some embodiments, the front-side edge coupler 45 can composed of silicon nitride (SiN), silicon oxynitride (SiON), polysilicon (poly-Si), polymeric materials and combinations thereof. In some embodiments, in which the front-side edge coupler 45 is composed of silicon nitride, the front-side edge coupler 45 may be formed by depositing a layer of silicon nitride (not shown) and then patterning the silicon nitride layer using photolithography and etching techniques. For example, a silicon nitride layer may be blanket deposited over the third dielectric layer 43 using a deposition technique, such as CVD, LPCVD, PVD, or the like. The etching process may include a dry etching process and/or a wet etching process. The front-side edge coupler 45 may have a tapered shape, a polygonal shape, a rectangular shape, a round shape, an irregular shape, or another shape.

In some embodiments, cladding may be formed surrounding the front-side edge coupler 45. By forming the cladding such that the front-side edge coupler 45 is covered by the cladding and laterally isolated by air, the loss of optical signal may be reduced. The cladding may be formed by forming an oxide layer over the front-side edge coupler 45.

FIG. 5 illustrates the optical fiber 95 connected to the front-side edge coupler 45. In some embodiments, the optical fiber 95 may be secured to the front-side edge coupler 45 using optical glue. In some embodiments, a fiber trench may be further employed to facilitate the engagement of support the optical fiber 95 and facilitate alignment of the optical fiber 95 with the front-side edge coupler 45. The fiber trench may be formed in the cladding adjacent to the front-side edge coupler 45 by photolithography and etching techniques.

FIG. 5 illustrates first metallization layers 51 that are formed in fourth dielectric layers 52 in order to electrically connect the first optical components 21 and control circuitry, to each other, and to subsequently attached devices (not illustrated in FIG. 5). In an embodiment, the first metallization layers 51 are formed of alternating layers of dielectric and conductive material and may be formed through any suitable processes (such as deposition, damascene, dual damascene, etc.). In particular embodiments there may be multiple layers of metallization used to interconnect the various first optical components 21, but the precise number of first metallization layers 51 is dependent upon the design of the PIC die 250. The fourth dielectric layers 52 may be composed of any of the aforementioned dielectric materials that are used for the second dielectric layer 40.

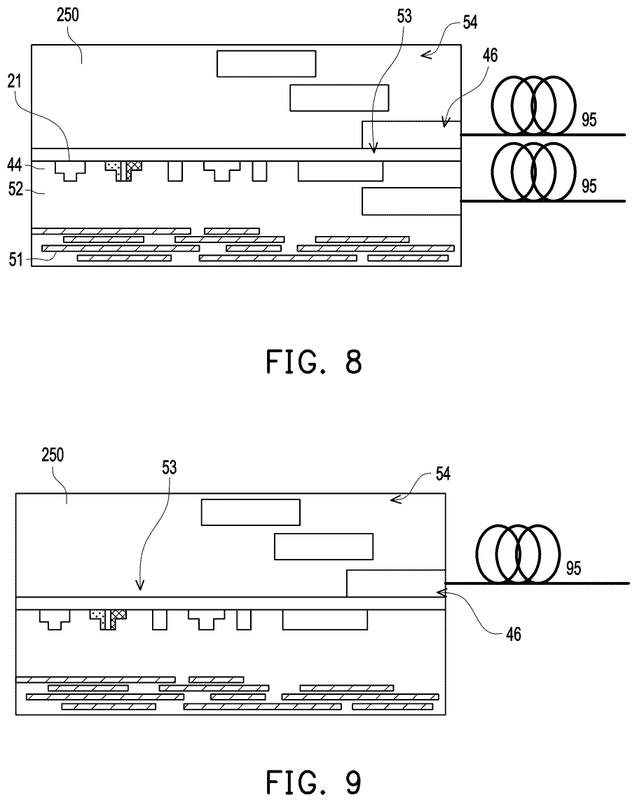

FIG. 5 illustrates one embodiment of an optical fiber 95 engaged to the front-side edge coupler 45 of a PIC die 250. The PIC die 250 illustrated in FIG. 5 may be co-packaged with EIC die 200 and logic die 150. However, the PIC die 250 depicted in FIG. 5 may be further processed to provide a back-side edge coupler 46 in combination with a front-side edge coupler 45. FIGS. 7 and 8 illustrate some embodiments of a process steps for integrating a back-side edge coupler 46 with the front-side edge coupler 45.

FIG. 7 illustrates that the PIC die 250 being flipped, and processed to remove the first substrate 11 and the first insulator layer 13. The first substrate 11 and the first insulator layer 13 may be removed using planarization and/or etching processes. For example, the first substrate 11 and the first insulator layer 13 may be removed using chemical mechanical planarization (CMP). Removing the first substrate 11 and the first insulator layer 13 exposes a back-side surface of the first optical components 21.

FIG. 8 illustrates forming a back-side edge coupler 46 on the back-side surface of the first optical components. The back-side edge coupler 46 may be formed using deposition, photolithography and etch processes similar to those used for forming the front-side edge coupler 45. For example, a fifth dielectric layer 53 may first be formed on the back-side edge coupler 46. The fifth dielectric layer 53 may be composed of any of the aforementioned dielectric materials that are used for the second dielectric layer 40. The fifth dielectric layer 53 may be formed using a deposition technique, such as CVD, LPCVD, PVD, or the like. The fifth dielectric layer 53 may be referred to as a regrown oxide layer. Following the formation of the fifth dielectric layer 53, the back-side edge coupler 46 may be formed. In some embodiments, the back-side edge coupler 46 can composed of silicon nitride (SiN), silicon oxynitride (SiON), polysilicon (poly-Si), polymeric materials and combinations thereof. The back-side edge coupler 46 may have a tapered shape, a polygonal shape, a rectangular shape, a round shape, an irregular shape, or another shape. In some embodiments, the edge coupler composed of silicon nitride that is integrated with a silicon nitride waveguide as illustrated in FIG. 6 may be employed as the back-side edge coupler 46 for the PIC die 250. Other optical devices may also be included within the backside processing, such as waveguides and/or modulators.

In some embodiments, cladding may be formed surrounding the back-side edge coupler 46. The cladding may be formed by forming an oxide layer over the back-side edge coupler 46. In some embodiments, the cladding may be accompanied by one or more sixth dielectric layer 54. The sixth dielectric layer 54 may be composed of any of the aforementioned dielectric materials that are used for the second dielectric layer 40, and the sixth dielectric layer 54 may be formed using any of the methods that have been described above for forming the second dielectric layer 40.

FIG. 8 illustrates one embodiment of an optical fiber 95 engaged to the back-side edge coupler 46 of a PIC die 250, as well as an optical fiber 95 engaged to a front-side edge coupler 45 of the PIC die 250. The above description for connecting an optical fiber 95 to the front-side edge coupler 45 is applicable for describing at least one example of connecting an optical fiber 95 to the back-side edge coupler 46. For example, the optical fiber 95 may be engaged to the back-side edge coupler 46 using an optical glue.

Similar to the PIC die 250 that is depicted in FIG. 5, the PIC die 250 illustrated in FIG. 8 includes both a front-side edge coupler 45 and a back-side edge coupler 46 may be co-packaged with EIC die 200 and logic die 150. However, it is not necessary that when employing a PIC die 250 with a back-side edge coupler 46 that a front-side edge coupler 45 also be present. For example, a PIC die 250 may employ only back-side edge couplers 46, while the front-side edge coupler 45, can be omitted, as depicted in FIG. 9. To provide the PIC die 250 that is depicted in FIG. 9, the process steps for forming the front-side edge coupler 45 may be omitted, and the back-side edge coupler 46 may be formed using the process steps that have been described above with reference to FIGS. 7 and 8.

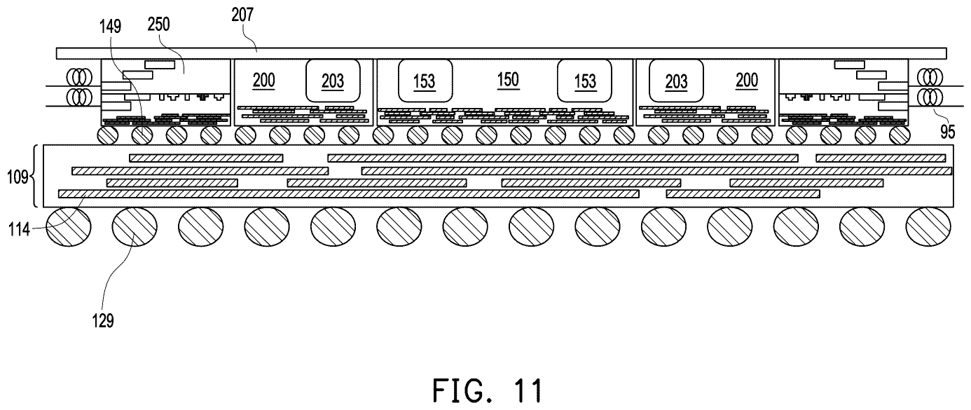

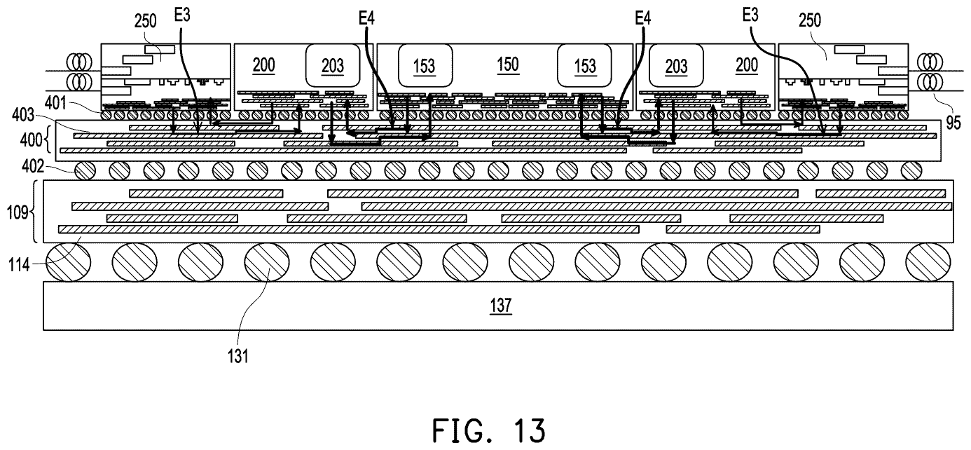

FIGS. 10 and 11 illustrates one embodiment of how the EIC die 200 that have been described above with reference to FIGS. 1 and 2, and the PIC die 250 that have been described with reference to FIGS. 3-9 are heterogeneously integrated into an electro-optical apparatus that also includes logic die 150, e.g., CMOS switch/SOC, as depicted in FIG. 13. In the embodiment depicted in FIGS. 9 and 10, the logic die 150, the EIC die 200 and the PIC die 250 are bonded to a redistribution layer (RDL) substrate 109, and the redistribution layer (RDL) substrate 109 is bonded to a packaging substrate 137.

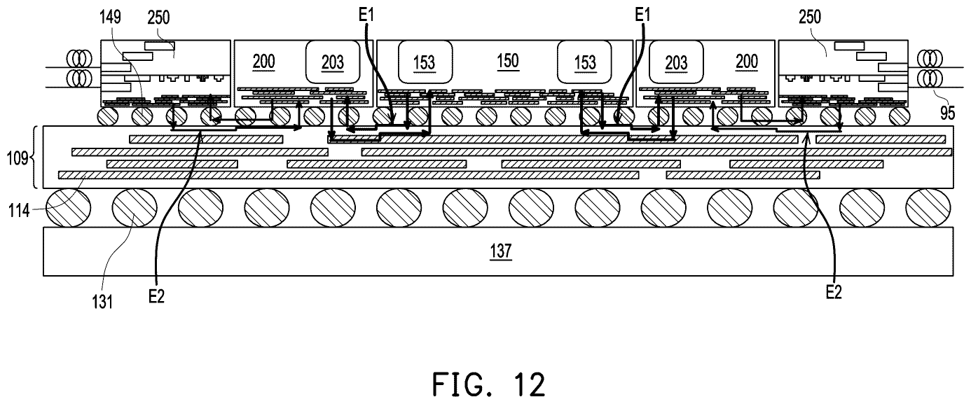

In FIG. 10, the redistribution layer (RDL) substrate 109 is formed on a first carrier substrate 107. The redistribution layer (RDL) substrate 109 includes one or more metal interconnect lines 114 that electrically connect subsequently bonded devices, such as the logic die 150, the EIC die 200 and the PIC die 250, to a subsequently bonded package substrate 137 (see FIG. 12) for signal and/or power routing. The redistribution layer (RDL) substrate 109 includes one or more metal interconnect lines 114 in electrical communication with bonding pads to connect to solder balls. The bond pads for the bonded devices, such as the logic die 150, the EIC die 200 and the PIC die 250, may be bonded to bond pads of the one or more metal interconnect lines 114.

The metal interconnect lines 114 may be formed in one or more layers of insulating material. In some embodiments, the one or more layers of insulating material in the redistribution layer (RDL) substrate 109 may have an organic composition. For example, the insulating material in the redistribution layer (RDL) substrate 109 may be a polymeric composition. In some examples, the insulating material in the redistribution layer (RDL) substrate 109 may be a polymer material, such as an epoxy. For example, the insulating material of the redistribution layer (RDL) substrate 109 may be an epoxy resin providing the matrix for a composite material, the composite material further including an amine based compound harder, filler materials including silica and/or alumina, flexabilizers, and/or curing agents. In other embodiments, the insulating material of the redistribution layer (RDL) substrate 109 may be a silicon containing inorganic material. In some embodiments, the insulating material in the redistribution layer (RDL) substrate 109 may have a dielectric constant of less than 3.5. For example, the insulating material in the redistribution layer (RDL) substrate 109 may have a dielectric constant of about 3.3.

The redistribution layer (RDL) substrate 109 may be formed using deposition processes, spin on processes, or the like forming the insulating materials, e.g., polymeric insulating materials. Openings and trenches for metal lines and/or traces may be formed using photolithography and etch processes. Further, a metal material, such as copper and/or aluminum, for the metal lines and/or traces may be formed using deposition processes, such as sputtering, plating processes, or the like. In some embodiments, the upper surface of the redistribution layer (RDL) substrate 109 (e.g., an upper layer of insulating material) may be planarized using a planarization process, such as chemical mechanical planarization (CMP).

In some embodiments, the redistribution layer (RDL) substrate 109 may be formed on a first carrier substrate 107 through a bonding layer. The first carrier substrate 107 may be formed of any rigid material, e.g., metal, glass and/or semiconductor material (e.g., silicon (Si). In some embodiments, the bonding layer may be a release film, which may be a Light-to-Heat Conversion (LTHC) layer.

FIGS. 10 and 11 illustrate the logic die 150, the EIC die 200 and the PIC die 250 being bonded to the upper surface of the redistribution layer (RDL) substrate 109. In some embodiments, the logic die 150, the EIC die 200 and the PIC die 250 may be bonded to the underlying redistribution layer (RDL) substrate 109, for example, through die solder bonds 149, as depicted in FIG. 11. In an example, the die solder bonds 149 may be provided by controlled collapse chip connection (C4) bumps. Although the bonding of the logic die 150, the EIC die 200 and the PIC die 250 to the underlying redistribution layer (RDL) substrate 109 is described using solder bonds, in some other embodiments, bonding may be provided using microbumps, direct bonding (copper-to-copper bonding) and/or hybrid bonding.

FIGS. 10 and 11 illustrate the bonding of the logic die 150, the EIC die 200 and the PIC die 250 to the redistribution layer (RDL) substrate 109 using a solder bonding/flip chip type process. The die solder bonds 149 provide for connection between the contacts pads of the one or more metal interconnect lines 114 and the contact pads of the logic die 150, the EIC die 200 and the PIC die 250. In an example, C4 solder bonds provides the die solder bonds 149 connecting the logic die 150, the EIC die 200 and the PIC die 250 to the redistribution layer (RDL) substrate 109, in which the solder bonds may have a bump size, e.g., diameter, of approximately 100 microns or greater. In some embodiments, the die solder bonds 149 may also be formed of lead free materials, such as SnAg, SnCu, SnAgCu. In some other cases, the die solder bonds 149 may be formed of PbAg. In some embodiments, the die solder bonds 149 may be formed using indirect bonding, mass reflow, thermal compression bonding, direct bonding, insert bump bonding and combinations thereof. It is noted that the above methods are provided for illustrative purposes only. Other examples of solder application methods include printing of solder paste, engraved mask stump, photosensitive organic mask and squeegee, electroplating of solder, evaporation, needle dispensing, solder paste printing, plated solder bumps, plated copper pillars with micro-bumps and combinations thereof.

Referring to FIG. 11, after the application of solder 148 (depicted in FIG. 10) to the contacts for the logic die 150, the EIC die 200 and the PIC die 250, the solder 148 may then be contacted to the contacts on the contact pads of the one or more metal interconnect lines 114 of the RDL substrate 109 under elevated temperature and pressure to effectuate bonding (e.g., forming die solder bonds 149). Following bonding, an underfill (not shown) may be applied. The underfill may be a thermoset epoxy or polymer that's applied to the die solder bonds 149 to protect them and strengthen solder joints. In some embodiments, the underfill may be applied after the solder bumps have gone through a reflow oven and may be dispensed using an automated syringe. The underfill may then be applied, in which the underfill flows underneath the logic die 150, the EIC die 200 and the PIC die 250 using capillary action. In some embodiments, after application, the underfill is cured by being heated.

Following the formation of the underfill, the structure may be encapsulated in an encapsulant (not shown), e.g., by over molding. For example, the structure including the logic die 150, the EIC die 200 and the PIC die 250 bonded to the redistribution layer (RDL) substrate 109, may be positioned within a mold, and a molding material may be injected into the mold to encapsulate the integrated circuit devices 120 to the redistribution layer (RDL) substrate 109. The molding material for the encapsulant may be an epoxy material. Following hardening of the encapsulant, the hardened structure may be planarized. For example, the encapsulant may be planarized using chemical mechanical planarization to expose upper surfaces of the logic die 150, EIC die 200 and the PIC die 250.

FIG. 11 illustrates the upper surface of the logic die 150, the EIC die 200 and the PIC die 250 being attached to a transfer substrate 207, e.g., tape structure. In some embodiments, the tape structure that provides the transfer substrate 207 may be an ultraviolet tape, although any other suitable adhesive or attachment may be used. In some embodiments, after the transfer substrate 207 is attached to the logic die 150, the EIC die 200 and the PIC die 250, the first carrier substrate 107 may be removed. For example, the first carrier substrate 107 may be debonded, for example, by projecting a laser beam on the release film, thus decomposing the release film. After removing the first carrier substrate 107, the back-side surface of the redistribution layer (RDL) substrate 109 is exposed.

FIG. 11 illustrates one embodiment of a solder bond process applied to the redistribution layer (RDL) substrate 109. In some embodiments, solder bumps 129 are formed on contacts to the one or more metal interconnect lines 114 of the redistribution layer (RDL) substrate 109. In some embodiments, the solder bumps 129 may be controlled collapse chip connection (C4) bumps. The solder bumps 129 may be used to bond the redistribution layer (RDL) substrate 109 to a package substrate 137, as depicted in FIG. 12. The packaging substrate 137 may be a printed circuit board (PCB). The term “solder”, as used herein, refers to any metal or metallic compound or alloy that is melted and then allowed to cool in order to join two or more metallic surfaces together. For example, solders have melting temperatures in the range of 150° C. to 250° C. Solder bumps may be small spheres of solder (solder balls) that are bonded to contact areas, interconnect lines or pads of semiconductor devices. In some embodiments, the solder bumps may be made from lead-free solder mixtures or lead tin solder.

In some embodiments, the solder bump process for forming the die solder bonds 131 (as depicted in FIG. 12) may include an in-situ sputter clean to remove oxides or photoresist prior to metal deposition on the contacts to the one or more metal interconnect lines 114. The cleaning may also serve to roughen the surface of the contacts (also referred to as bond pads) in order to promote better adhesion of the under ball metallization (UBM). A metal mask having an array pattern may be used to pattern the structure for UBM and bump deposition. In some embodiments, a sequential evaporation of a chromium layer, a phased chromium/copper layer, a copper layer and a gold layer are deposited to form a thin film under ball metallurgy (UBM) on the contacts to the one or more metal interconnect lines 114. In one example, lead-tin solder is then evaporated on top of the UBMs to form thick layers of solder. The height of the resulting solder bumps are determined by the volume of the evaporated material that is deposited. This is also a function of the distance between the metal mask and the wafer, as well as the sizes of the mask openings. The deposited solder may be conical in shape, due to the way that the solder is formed in the openings of the solder mask. The solder may be reflowed to form spheres.

In FIG. 12 the assembly including redistribution layer (RDL) substrate 109 bonded to the logic die 150, the EIC die 200 and the PIC die 250 is bonded through package solder bonds 131 to a first side of a package substrate 137. The bonding may be by flip chip bonding (FCB). The package substrate 137 may be a cored substrate or a non-cored substrate. In some embodiments, the package substrate 137 may be a printed circuit board (PCB). A printed circuit board (PCB) is an electronic assembly that uses copper conductors to create electrical connections between components. In some embodiments, the PCB employed for the package substrate 137 may be built from alternating layers of conductive copper with layers of electrically insulating material. In some embodiments, the package substrate 137 may be a semiconductor material substrate, such as a type IV or type III-V semiconductor substrate. In one example, the package substrate 137 may be formed of a silicon containing material, e.g., a silicon (Si) substrate, or a germanium containing material, e.g., a silicon germanium (SiGe) substrate.

After the formation of the solder bumps 129 (as depicted in FIG. 11), the assembly including redistribution layer (RDL) substrate 109 bonded to the logic die 150, the EIC die 200 and the PIC die 250 is flipped and the solder bumps 129 are aligned with contact pads (also referred to as bond pads) to the metal interconnect lines of the package substrate 137. In some embodiments, the accuracy of alignment may be of the order of a few microns for reliable function. Once the assembly including redistribution layer (RDL) substrate 109 bonded to the logic die 150, the EIC die 200 and the PIC die 250 is aligned and flipped on the package substrate 137, the solder bumps 129 are reflowed to spread the conductive material evenly across the bond pads of the package substrate 137 forming package solder bonds 131, as depicted in FIG. 12. In some embodiments, the packaging solder bonds 131 may also be referred to as a ball grid array (BGA).

Additionally, an underfill (not shown) may be formed between the redistribution layer (RDL) substrate 109 and the package substrate 137. The underfill may also be referred to as a chip on wafer (COW) molding. The underfill may be deposited on the edges of the redistribution layer (RDL) substrate 109, so that it flows across the gap between the redistribution layer (RDL) substrate 109 and the package substrate 137 by capillary action, filling the space between the package solder bonds 131. The transfer substrate 207 may be removed.

FIG. 12 illustrates heterogeneous integration of the PIC die 250, the EIC die 200 including the high-voltage high-speed SiGe/III-V based transistors, and the logic die 150, e.g., CMOS switch/SOC die. The PIC die 250 and EIC die 200 are coupled with signals E2 that are high-voltage, e.g., having an operating voltage greater than 3.5V, and high-frequency, e.g., having a transmission rate of approximately 100GHz/400Gbps or greater. The coupling of the PIC die 250 and EIC die 200 are through the die solder bonds 149, and the metal interconnect lines 114 of the redistribution layers (RDL) substrate 109. The EIC die 200 and the logic die 150 are coupled with signals E1 that are at the highest transmission frequency capability of the silicon-based transistors in the CMOS circuits of the logic die 150, which may be 50 GHz/200 Gbps or less. The coupling of the logic die 150 and the EIC die 200 are also through the die solder bonds 149, and the metal interconnect lines 114 of the redistribution layers (RDL) substrate 109. The transmission of signal E1 between the logic die 150 and the EIC die 200 is processed with two stages of signal serialization, as described above with reference to FIG. 2. For example, a first serialization device 153 for the first stage of signal serialization is present in the logic die 150, and a second serialization device 201 for the second stage of signal serialization is present in the EIC die 200. The high conductivity passageways provided by the bonding, e.g., C4 solder bonding; the high speed type III-V or SiGe based semiconductor devices of the EIC die 200; and the serialization/deserialization scheme described above with reference to FIG. 2 are each factors that contribute to the PIC die 250 being able to transmit extremely high-frequency (e.g. 100 GHz or 400 Gbps) optical signals for long distance, e.g., distances ranging from approximately 10 m to approximately 2 km.

FIG. 13 shows another embodiment for heterogeneously integrating the PIC die 250, EIC die 200, and the logic die 150, e.g., CMOS switch/SOC, into an electro-optical package. The electro-optical package that is depicted in FIG. 13 is similar to the electro-optical package that has been described above with reference to FIG. 12. However, the electro-optical package that is depicted in FIG. 13 further includes an interposer substrate 400 between the RDL substrate 109 and the PIC die 250, the EIC die 200, and the logic die 150. Further, the PIC die 250, the EIC die 200 and the logic die 150 may be bonded to the interposer substrate 400 using first interposer bonds 401 provided by microbumps, direct bonding (copper-to-copper bonding) and/or hybrid bonding.

In some embodiments, the interposer substrate 400 features at least one redistribution layer (RDL) and at least one through insulator via (TIV) (also referred to through InFO via) for providing electrical communication between dies, e.g., the logic die 150, the EIC die 200 and the PIC die 250. In some examples, a local silicon interconnect (LSI) chip may also be included in the interposer substrate 400 for die-to-die interconnects for power and signal delivery. The circuitry of the interposer substrate 400 can also provide for interconnectivity of the PIC die 250, the EIC die 200 and the logic die 150 to the RDL substrate 109 that is bonded to the opposing side of the interposer substrate 400. The circuitry of the interposer substrate 400 may be collectively referred to as interposer interconnect lines 403.

The first interposer bonds 401 between the upper surface of the interposer substrate 400 and the PIC die 250, the EIC die 200, and the logic die 150 may be provided by microbump solder bonds, hybrid bonding and/or direct bonding. Direct bonding may be provided using copper-to-copper bonding. The copper-to-copper bonding method involves directly bonding copper connections between stacked dies, e.g., the PIC die 250 and the interposer substrate 400, the EIC die 200 and the interposer substrate 400, and the logic die 150 and the interposer substrate 400. The copper connections that are bonded together may include copper pads in each of the structures being bonded together, e.g., the interposer substrate 400 and the logic die 150/EIC die 200/PIC die 250. In some embodiments, the first interposer bonds 401 provided by copper to copper bonding allows for higher density and improved performance compared to methods like solder bumps and pillars.

In some embodiments, the copper-to-copper bonding method can include preparing the surfaces of the copper pads on each die, e.g., the logic die 150, the EIC die 200, the PIC die 250 and the interposer substrate 400, are prepared and cleaned to ensure a strong bond. The copper-to-copper bonding method also includes aligning the dies so that the copper pads on each die (the logic die 150, the EIC die 200, the PIC die 250 and the interposer substrate 400) match up perfectly. In a following process sequence, the copper-to-copper bonding method involves the dies (the logic die 150, the EIC die 200, the PIC die 250 and the interposer substrate 400) being pressed together, and the copper pads bond through a process of diffusion, creating a direct electrical connection. In some embodiments, the first interposer bonds 401 provided by the copper-to-copper bonding can be achieved with bond pads as small as 0.25 μm at a pitch of 0.5 μm. In some embodiments, dielectric material between the bond pads of each of the structures being bonded to one another also form bonds when brought into contact with one another during the process by which the copper-to-copper bonds form. The bonding resulting from the copper-to-copper bonds and the dielectric material to dielectric material bonds results in a hybrid bond.

In some other embodiments, the first interposer bonds 401 between the logic die 150, the EIC die 200, the PIC die 250 and the interposer substrate 400 may be provided by microbumps. A microbump process includes forming raised metal bumps on the bonding surfaces of the logic die 150, the EIC die 200, the PIC die 250 and the interposer substrate 400, which act as electrical connection points for connecting multiple chips or layers within an integrated circuit package, allowing for high-density interconnections and enabling 3D stacking. In some embodiments, the microbumps that provides the first interposer bonds 401 may be composed of metals like copper, with a solder cap for improved reliability. In some embodiments, methods for forming the microbumps include electroplating, photolithography, and screen printing. In some embodiments, the microbumps may have a diameter ranging from 20 microns to 30 microns.

In some embodiments, the logic die 150, the EIC die 200 and the PIC die 250 are first bonded to the interposer substrate 400 to provide a chip on interposer structure. Thereafter, the chip on interposer structure is bonded to an RDL substrate 109. Bonding the logic die 150, the EIC die 200 and the PIC die 250 to the interposer substrate 400 is similar to above described process for bonding the logic die 150, the EIC die 200 and the PIC die 250 to the RDL substrate 109 that is described above with reference to FIGS. 10 and 11. However, in the embodiment depicted in FIG. 13, the first interposer bonds 401 between the interposer substrate 400 and the logic die 150/EIC die 200/PIC die 250 may be copper to copper direct bonding or microbump bonding. After forming the first interposer bond 401 between the interposer substrate 400 and the logic die 150/EIC die 200/PIC die 250, underfill and encapsulate may be applied, as described for the embodiment depicted in FIGS. 10-12.

The chip on interposer structure including the logic die 150, the EIC die 200 and the PIC die 250 that is bonded to the interposer substrate 400 may then be bonded to a redistribution layer (RDL) substrate 109. The redistribution layer (RDL) substrate 109 that is depicted in FIG. 13 is similar to the redistribution layer (RDL) substrate 109 that has been described above with reference to FIGS. 10-12. The second interposer bonds 402 for bonding the chip on interposer structure the logic die 150, the EIC die 200 and the PIC die 250 to the RDL substrate 109 may be copper to copper direct bonding or microbump bonding. The above description of direct bonding and microbump bonding for providing the first interposer bonds 401 between the interposer substrate 400 and the logic die 150, the EIC die 200 and the PIC die 250 is suitable for providing the description of at least one embodiment for the second interposer bonds 402 between the interposer substrate 400 and the upper surface of the RDL substrate 109. After the chip on interposer structure is bonded to the RDL substrate 109, the entire assembly may then be bonded to the packaging substrate 137.

FIG. 13 illustrates that the RDL substrate 109 is bonded to a packaging substrate 137. The packaging substrate 137 that is depicted in FIG. 13 has been described above with reference to FIGS. 9-12. The package solder bonds 131 between the RDL substrate 109 and the packaging substrate 137 may be provided by solder bumps, such as C4 solder bumps. In some embodiments, solder bumps are formed on contacts to the one or more metal interconnect lines 114 of the redistribution layer (RDL) substrate 109. Processing to provide package solder bonds 131 from the solder bumps has been described above with reference to FIGS. 11 and 12. The package solder bonds 131 employed to bond the RDL substrate 109 to a package substrate 137 that are depicted in FIG. 13 are similar to the die solder bonds 149 used to bond the logic die 150, the EIC die 200 and the PIC die 250 to the RDL substrate 109 that is depicted in FIG. 12. Therefore, the description of the die solder bonds 149 depicted in FIG. 12 is suitable for describing forming the package solder bonds 131 depicted in FIG. 13.

FIG. 13 illustrates another embodiment of heterogeneous integration of the PIC die 250, the EIC die 200 including the high-voltage high-speed SiGe/III-V based transistors, and the logic die 150, e.g., CMOS switch/SOC die in an optical electrical packaged apparatus. The PIC die 250 and EIC die 200 are coupled with signals E2 that are high-voltage, e.g., having an operating voltage greater than 3.5V, and high-frequency, e.g., having a transmission rate of approximately 100 GHz/400 Gbps or greater. The coupling of the PIC die 250 and EIC die 200 are through the first interposer bonds 401, e.g., microbumps, direct bonding and/or hybrid bonding, and the interposer interconnect lines 403 of the interposer substrate 400. The EIC die 200 and the logic die 150 are coupled with signals E1 that are at the highest transmission frequency capability of the silicon-based transistors in the CMOS circuits of the logic die 150, which may be 50 GHz/200 Gbps or less. The coupling of the PIC die 250 and the EIC die 200 are also through the first interposer bonds 401, e.g., microbumps, direct bonding and/or hybrid bonding, and the interposer interconnect lines 403 of the interposer substrate 400. The transmission of signal E1 between the logic die 150 and the EIC die 200 is processed with two stages of signal serialization, as described above with reference to FIG. 2. For example, a first serialization device 153 for the first stage of signal serialization is present in the logic die 150, and a second serialization device 203 for the second stage of signal serialization is present in the EIC die 200. The high conductivity passageways provided by the bonding, e.g., first interposer bonds 401 provided by microbumps, direct bonding and/or hybrid bonding; the high speed type III-V or SiGe based transistors of the EIC die 200; and the serialization/deserialization scheme described above with reference to FIG. 2 are each factors that contribute to the PIC die 250 being able to transmit extremely high-frequency (e.g. 100 GHz or 400 Gbps) optical signals for long distance, e.g., distances ranging from approximately 10 m to approximately 2 km.

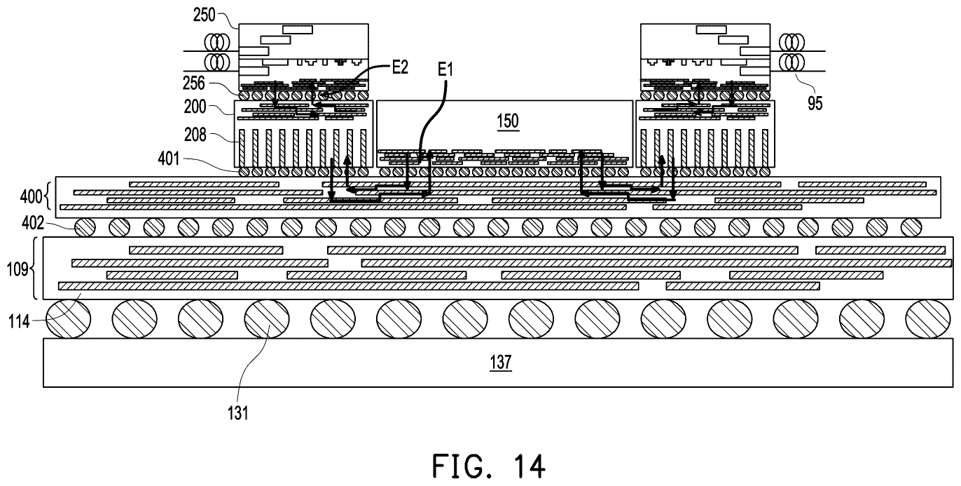

FIG. 14 depicts yet another embodiment, in which the PIC die 250 is vertically stacked and bonded atop an upper surface of the EIC die 200. In this embodiment, signal transmission E2 between the EIC die 200 and the PIC die 250 is vertically orientated. In some embodiments, a base surface of the PIC die 250 is bonded to a top surface of the EIC die 200 through a vertical stack bond 256. The vertical stack bond 256 may be a microbump bond, a direct bond (copper to copper bond) or hybrid bond. The vertical stack bond 256 is similar to the first interposer bonds 401 that have been described above with reference to FIG. 12. Vertical signal transmission through the EIC die 200 may be provided by one or more vertical interconnect vias 208, e.g., through insulator via (TIV) and/or through silicon via (TSV), which can be a copper based conductive structures that may have a pillar like geometry. It is noted that the embodiment depicted in FIG. 14 is similar to the embodiments described above with reference to FIGS. 12 and 13. Therefore, elements illustrated in FIG. 14 having reference numbers that are also illustrated as elements in FIGS. 12 and 13 may be equivalent for the purposes of description. Although the vertical stacking of the PIC die 250 and the EIC die 200 is illustrated in an embodiment that employs an interposer substrate 400, vertical stacking of the PIC die 250 and the EIC die 200 is not limited to only this embodiment. For example, the vertical stacking of the PIC die 250 and the EIC die 200 can be integrated into the embodiment that is depicted in FIG. 12.

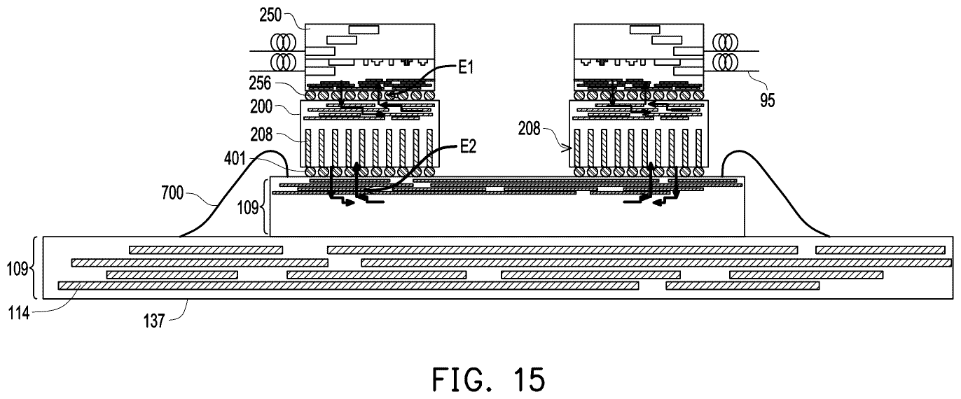

FIG. 15 illustrates yet another embodiment, in which the RDL substrate 109 is connected to a packaging substrate 137 through wire bonds 700. In this embodiment, the solder bonds between the RDL substrate 109 and the packaging substrate 137 may be omitted. In some embodiments, the wire bonds 700 may provide for power/ground transmission and/or low-frequency transmission from the RDL substrate 109 to a packaging substrate 137. In this example, the RDL substrate 109 may be adhesively bonded or mechanically engaged to the packaging substrate 137. FIG. 15 further illustrates heterogeneous integration of the PIC die 250, the EIC die 200 including the high-voltage high-speed SiGe/III-V based transistors, and logic die 150, e.g., CMOS switch/SOC die, in an electro-optical assembly. The heterogeneous integration of the PIC die 250, EIC die 160 and logic die 150 into an electro-optical assembly can be provided using any of the methods and structures that have been described above with reference to FIGS. 1-14.

In some embodiments, the methods and structures described herein can provide a number of advantages. The co-packaged electric-optical apparatuses are capable of driving high-speed modulators with high-operating voltages. In some embodiments, the co-packaged electric-optical apparatuses that include an EIC die including type III-V transistors and/or silicon germanium transistors that can enlarge the Optical Modulation Amplitude (OMA) by providing a large swing for the trans-impedance-Amplifier (TIA) when compared to similarly configured EIC die including silicon based transistor CMOS arrangements. The methods and structures described herein may also eliminate the bandwidth limit from CMOS driving/receiving circuits with lesser amounts serialization/deserialization, which may improve transmission energy efficiency. In some embodiments, the methods and structures described herein can attain higher data transfer energy efficiency. For example, the electro optical apparatuses described herein can transmit extremely high-frequency, e.g. 100 GHz or 400 Gbps, optical signals for significantly long distance, e.g., ranging from 10 m to 2 km.

In accordance with an embodiment, a method includes bonding a logic die to a first portion of a substrate, wherein the logic die includes a first signal serialization device and the substrate includes at least one redistribution layer; bonding an Electrical Integrated Circuit (EIC) die to a second portion of the substrate, the EIC die comprises type III-V devices, silicon germanium channel devices, or a combination of type III-V devices and silicon germanium channel devices, the EIC die includes a second signal serialization device, wherein a first portion of the at least one redistribution layer of the substrate provides for a first signal transmission path between the logic die and the EIC die; and bonding a Photonic Integrated Circuit (PIC) die to a third portion of the substrate, wherein a second portion of the at least one redistribution layer of the substrate provides for a second signal transmission path between the PIC die and the EIC die. In an embodiment, an electrical signal is transmitted through the first signal transmission path at a first transmission rate, and the electrical signal is transmitted through the second signal transmission path at a second transmission rate, the second transmission rate being greater than the first transmission rate. In an embodiment, the PIC die comprises an edge coupler. In an embodiment, the edge coupler comprises a nitride containing material. In an embodiment, the method further includes attaching an optical fiber to the edge coupler. In an embodiment, the bonding of the logic die to the substrate, the bonding of the EIC die to the substrate, and the bonding of the PIC die to the substrate comprises solder bonding, microbump bonds, copper to copper bonds, hybrid bonds or combinations thereof. In an embodiments, the first signal serialization device performs a first signal serialization of electrical signal for transmission through the first signal transmission path, and the second signal serialization device performs a second signal serialization of the electrical signal for transmission through the second signal transmission path, and wherein the second signal serialization is greater than the first signal serialization. In accordance with another embodiment, a method includes bonding a logic die to a first portion of a substrate, wherein the logic die includes a first signal serialization device and the substrate includes at least one redistribution layer; bonding an Electrical Integrated Circuit (EIC) die to a second portion of the substrate, the EIC die comprises III-V type devices, silicon germanium channel devices, or a combination of III-V type devices and silicon germanium type devices, and the EIC die includes a second signal serialization device, wherein a portion of the at least one redistribution layer of the substrate provides for first signal transmission path between the logic die and the EIC die; and bonding a Photonics Integrated Circuit (PIC) die to the EIC die, wherein a second signal transmission path is vertically orientated and between PIC die and the EIC die. In an embodiment, the electrical signal transmission through the first signal transmission path is at a first transmission rate, and the electrical signal transmission through the second signal transmission path is at a second transmission rate, the second transmission rate being greater than the first transmission rate. In an embodiment, the bonding of the logic die to the substrate, the bonding of the EIC die to the substrate, and the bonding of the PIC die to the EIC die comprises microbump bonds, copper to copper bonds, hybrid bonds or combinations thereof. In an embodiment, the first signal serialization device performs a first signal serialization for transmission of electrical signal through the first signal transmission path, and the second signal serialization device performs a second signal serialization for transmission of the electrical signal through the second signal transmission path, the second signal serialization is greater than the first signal serialization. In an embodiment, the PIC die comprises an edge coupler. In an embodiment, the edge coupler comprises a nitride containing material.

In accordance with yet another embodiment, a device includes a logic die bonded to a first portion of a substrate, wherein the logic die includes a first signal serialization device and the substrate includes at least one redistribution layer; an Electrical Integrated Circuit (EIC) die bonded to a second portion of the substrate, the EIC die comprises III-V type devices, silicon germanium channel devices, or a combination of III-V type devices and silicon germanium channel devices, the EIC die includes a second signal serialization device, wherein a second portion of the at least one redistribution layer of the substrate provides for a first signal transmission path between the logic die and the EIC die; and a Photonics Integrated Circuit (PIC) die, wherein a second signal transmission path extends between the PIC die and the EIC die. In an embodiment, the logic die comprises silicon-based transistors. In an embodiment, the PIC die is bonded to a third portion of the substrate, wherein a third portion of the at least one redistribution layer of the substrate provides the second signal transmission path that extends between the PIC die and the EIC die. In an embodiment, the bonding of the logic die to the substrate, the bonding of the EIC die to the substrate, and the bonding of the PIC die to the substrate comprises copper to copper bonding, hybrid bonding or a combination of copper to copper bonding and hybrid bonding. In an embodiment, the PIC die is bonded to the EIC die. In an embodiment, the bonding of the logic die to the substrate, the bonding of the EIC die to the substrate, and the bonding of the PIC die to the EIC comprises copper to copper bonding, hybrid bonding or a combination of copper to copper bonding and hybrid bonding. In an embodiment, the PIC die further comprises an edge coupler. In an embodiment, the edge coupler comprises a nitride containing material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
bonding a logic die to a substrate, wherein the logic die includes a first signal serialization device and the substrate includes at least one redistribution layer;
bonding an Electrical Integrated Circuit (EIC) die to the substrate, the EIC die comprising type III-V devices, silicon germanium channel devices, or a combination of type III-V devices and silicon germanium channel devices, the EIC die includes a second signal serialization device, wherein a first portion of the at least one redistribution layer of the substrate provides for a first signal transmission path between the logic die and the EIC die; and
connecting a Photonic Integrated Circuit (PIC) die to the EIC die and the substrate.

2. The method of claim 1, wherein an electrical signal is transmitted through the first signal transmission path at a first transmission rate, and the electrical signal is transmitted through a second signal transmission path at a second transmission rate, the second transmission rate being greater than the first transmission rate.

3. The method of claim 1, wherein the PIC die comprises an edge coupler.

4. The method of claim 3, wherein the edge coupler comprises a nitride containing material.

5. The method of claim 3, further comprising attaching an optical fiber to the edge coupler.

6. The method of claim 1, wherein the bonding of the logic die to the substrate, the bonding of the EIC die to the substrate, and the bonding of the PIC die to the substrate comprises solder bonding, microbump bonds, copper to copper bonds, hybrid bonds or combinations thereof.

7. The method of claim 1, wherein the first signal serialization device performs a first signal serialization of electrical signal for transmission through the first signal transmission path, and the second signal serialization device performs a second signal serialization of the electrical signal for transmission through the second signal transmission path, and wherein the second signal serialization is greater than the first signal serialization.

8. A method comprising:
bonding a logic die to a first portion of a substrate, wherein the logic die includes a first signal serialization device and the substrate includes at least one redistribution layer;
bonding an Electrical Integrated Circuit (EIC) die to a second portion of the substrate, the EIC die comprises III-V type devices, silicon germanium channel devices, or a combination of III-V type devices and silicon germanium channel devices, and the EIC die includes a second signal serialization device, wherein a portion of the at least one redistribution layer of the substrate provides for first signal transmission path between the logic die and the EIC die; and
bonding a Photonics Integrated Circuit (PIC) die to the EIC die, wherein a second signal transmission path is vertically orientated and between PIC die and the EIC die.

9. The method of claim 8, wherein electrical signal transmission through the first signal transmission path is at a first transmission rate, and the electrical signal transmission through the second signal transmission path is at a second transmission rate, the second transmission rate being greater than the first transmission rate.

10. The method of claim 8, wherein the bonding of the logic die to the substrate, the bonding of the EIC die to the substrate, and the bonding of the PIC die to the EIC die comprises microbump bonds, copper to copper bonds, hybrid bonds or combinations thereof.

11. The method of claim 8, wherein the first signal serialization device performs a first signal serialization for transmission of electrical signal through the first signal transmission path, and the second signal serialization device performs a second signal serialization for transmission of the electrical signal through the second signal transmission path, the second signal serialization is greater than the first signal serialization.

12. The method of claim 11, wherein the PIC die comprises an edge coupler.

13. The method of claim 12, wherein the edge coupler comprises a nitride containing material.

14. A device comprising:
a logic die bonded to a first portion of a substrate, wherein the logic die includes a first signal serialization device and the substrate includes at least one redistribution layer;
an Electrical Integrated Circuit (EIC) die bonded to a second portion of the substrate, the EIC die comprises III-V type devices, silicon germanium channel devices, or a combination of III-V type devices and silicon germanium channel devices, the EIC die includes a second signal serialization device, wherein a second portion of the at least one redistribution layer of the substrate provides for a first signal transmission path between the logic die and the EIC die; and
a Photonics Integrated Circuit (PIC) die, wherein a second signal transmission path extends between the PIC die and the EIC die.

15. The device of claim 14, wherein the logic die comprises silicon-based transistors.

16. The device of claim 14, wherein the PIC die is bonded to a third portion of the substrate, wherein a third portion of the at least one redistribution layer of the substrate provides the second signal transmission path that extends between the PIC die and the EIC die.

17. The device of claim 14, wherein the PIC die is bonded to the EIC die.

18. The device of claim 17, wherein the bonding of the logic die to the substrate, the bonding of the EIC die to the substrate, and the bonding of the PIC die to the EIC comprises copper to copper bonding, hybrid bonding or a combination of copper to copper bonding and hybrid bonding.

19. The device of claim 14, wherein the PIC die further comprises an edge coupler.

20. The device of claim 19, wherein the edge coupler comprises a nitride containing material.
